(19) United States
(12) Patent Application Publication
(10) Pub. No.: US 2026/0211340 A1
(43) Pub. Date: Jul. 23, 2026

(54) STAGE APPARATUS, SUBSTRATE PROCESSING APPARATUS AND ARTICLE MANUFACTURING METHOD

(71) Applicant: CANON KABUSHIKI KAISHA, Tokyo (JP)

(72) Inventors: YUICHI OZAWA, Tochigi (JP); SHOHEI IWATA, Tochigi (JP)

(21) Appl. No.: 19/430,878

(22) Filed: Dec. 23, 2025

(30) Foreign Application Priority Data
Jan. 22, 2025 (JP) 2025-009332

(51) Int. Cl. G03F 7/00

(52) U.S. Cl. CPC G03F 7/70766; G03F 7/70725; G03F 7/70758; G03F 7/709

(57) ABSTRACT

A stage apparatus including a stage configured to hold an object, a driving unit configured to drive the stage, a thrust unit configured to output a thrust to reduce influence of a reaction force associated with the driving of the stage by the driving unit, and a generation unit configured to generate a thrust signal indicating the thrust that the thrust unit should output, based on a profile signal indicating a control target of the stage and an operation signal indicating an operation amount of the stage to be input to the driving unit.

### BACKGROUND

### Field of the Technology

The present disclosure relates to a stage apparatus, a substrate processing apparatus and an article manufacturing method.

### Description of the Related Art

As disclosed in Japanese Patent Laid-Open No. 2001-110717, in a stage apparatus, a reaction force processing mechanism including a linear motor is attached to a stage, a stage base, or a base surface plate supporting the stage base to cancel a reaction force (acting force) generated when driving (stepping) the stage. The thrust of the reaction force processing mechanism is generated based on the drive profile signal of the stage or an input signal to a driving mechanism for driving the stage and is generated as a feedforward instruction value at the same time as the driving of the stage.

To generate the input signal to the reaction force processing mechanism, generally, stage driving is performed in a stage state serving as a reference, a reaction force associated with the stage driving is measured by an acceleration sensor or the like, and a filter to the input signal from the stage, which eliminates the reaction force, is designed.

However, if the dynamic characteristic of the stage varies due to a position change or aging of the stage, an error may be generated from the filter generated in the reference stage state, and omissions may occur in reaction force cancellation. Also, with the thrust generated from only the drive profile signal of the stage or the input signal to the driving mechanism for driving the stage, it is difficult to maintain stable and accurate cancellation of the reaction force associated with stage driving. In this case, thrust leakage occurs, and deformation or vibration may be caused in the stage base or the base surface plate by a leak thrust force.

### SUMMARY

The present disclosure provides a technique advantageous in reducing the influence of a reaction force associated with driving of a stage.

According to one aspect of the present disclosure, there is provided a stage apparatus including a stage configured to hold an object, a driving unit configured to drive the stage, a thrust unit configured to output a thrust to reduce influence of a reaction force associated with the driving of the stage by the driving unit, and a generation unit configured to generate a thrust signal indicating the thrust that the thrust unit should output, based on a profile signal indicating a control target of the stage and an operation signal indicating an operation amount of the stage to be input to the driving unit.

Further aspects of the present disclosure will become apparent from the following description of exemplary embodiments with reference to the attached drawings.

### BRIEF DESCRIPTION OF THE DRAWINGS

FIG. 1 is view illustrating an example of hardware configurations of a stage apparatus according to an aspect of the present disclosure.

FIG. 2 is a block diagram concerning the control system of the stage apparatus.

FIGS. 3A and 3B are views for explaining an effect of reducing the influence of a reaction force associated with driving of a stage.

FIG. 4 is a block diagram illustrating an example of the internal configuration of a first controller.

FIG. 5 is a block diagram illustrating an example of the internal configuration of a second controller.

FIG. 6 is a schematic view illustrating configurations of an exposure apparatus according to an aspect of the present disclosure.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

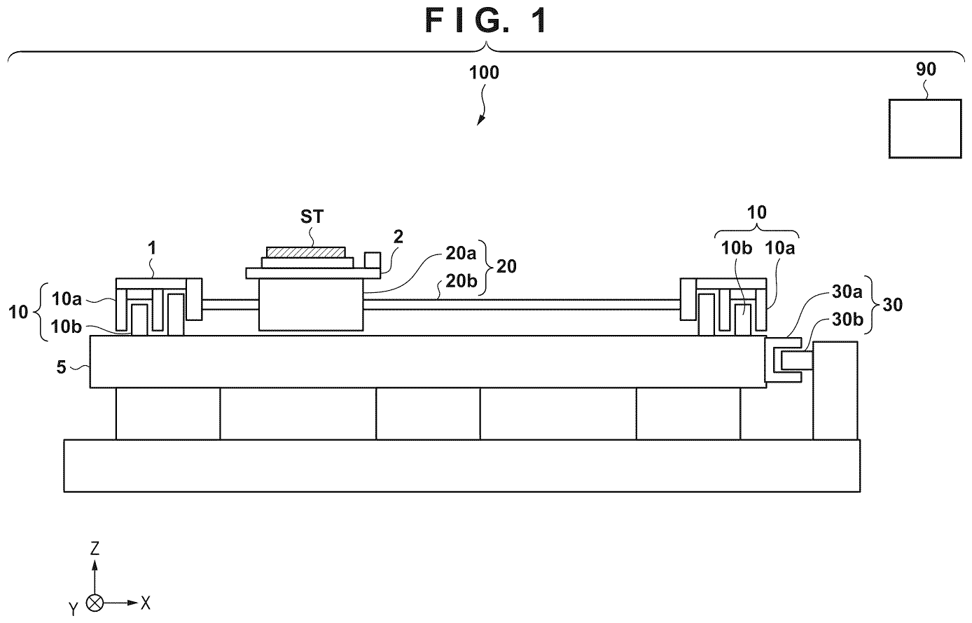

FIG. 1 is view illustrating an example of hardware configurations of a stage apparatus 100 according to an aspect of the present disclosure. The stage apparatus 100 is a holding apparatus configured to hold an object and is embodied as a holding apparatus configured to hold a substrate ST that is an object via a stage in this embodiment. The stage apparatus 100 is applied to, for example, a substrate processing apparatus that processes the substrate ST.

In this specification and accompanying drawings, directions are indicated on an XYZ coordinate system for which a direction parallel to a surface with the substrate ST arranged thereon is defined as an XY plane. Directions parallel to the X-, Y-, and Z-axes of the XYZ coordinate system are defined as the X direction, the Y direction, and the Z direction, respectively, and rotation about the X-axis, rotation about the Y-axis, and rotation about the Z-axis are defined as OX, OY, and OZ, respectively.

As shown in FIG. 1, the stage apparatus 100 includes a base 5, a first stage 1 capable of moving, for example, reciprocally moving on the base in the X direction (first direction), and a first driving unit 10 formed by a movable element 10a and a stator 10b and configured to drive the first stage 1. The stage apparatus 100 also includes a second stage 2 capable of moving, for example, reciprocally moving on the first stage in the Y direction (second direction different from the first direction), and a second driving unit 20 formed by a movable element 20a and a stator 20b and configured to drive the second stage 2. Furthermore, the stage apparatus 100 includes a reaction force processing mechanism 30 formed by a movable element 30a and a stator 30b and configured to output a reaction force for canceling a reaction force (acting force) associated with driving of the first stage 1 and the second stage 2 by the first driving unit 10 and the second driving unit 20. In this embodiment, the reaction force processing mechanism 30 functions as a thrust unit that outputs a thrust for reducing the influence of the reaction force associated with driving of the first stage 1 and the second stage 2.

The stage apparatus 100 includes a control unit 90 that generally controls the operation of the entire stage apparatus 100. The control unit 90 is formed by, for example, a computer (information processing apparatus) including a CPU, a memory, and the like and generally controls the units of the stage apparatus 100 in accordance with a program stored in a storage unit or the like.

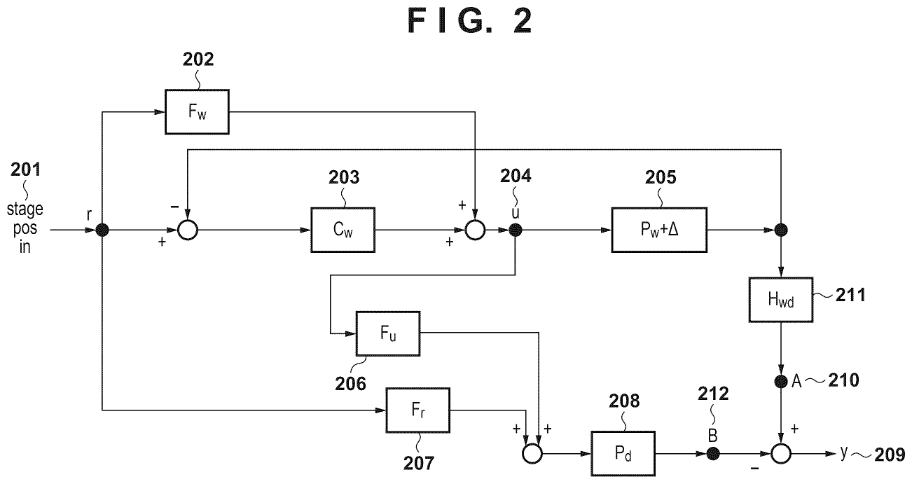

FIG. 2 is a block diagram concerning the control system of the stage apparatus 100. In FIG. 2, each block is indicated by transfer function expression. Note that in FIG. 2, the first stage 1 and the second stage 2 will be generically referred to as a stage 205, and the driving unit (the first driving unit 10 and the second driving unit 20) for driving the stage 205 will be referred to as a driving circuit.

Referring to FIG. 2, the input signal to be input to the reaction force processing mechanism 30 is generated based on a drive profile signal 201 indicating the drive profile of the stage 205 and a circuit input signal 204 input to the driving circuit. In this embodiment, a first controller 207 for the drive profile signal 201 and a second controller 206 for the circuit input signal 204 are provided as individual controllers. Hence, a synthetic signal of the signal generated by the first controller 207 and the signal generated by the second controller 206 is input as an input signal to the reaction force processing mechanism 30.

Here, the drive profile signal 201 is a profile signal indicating the control target of the stage 205 and is, in this embodiment, a position profile signal that indicates the trajectory of the target position of the stage 205 as the control target of the stage 205. However, the drive profile signal 201 is not limited to the position profile signal, and may be a velocity profile signal that indicates the transition of the target velocity of the stage 205 as the control target of the stage 205. Also, the circuit input signal 204 is an operation signal indicating the operation amount of the stage 205 input to the driving circuit.

The stage 205 is controlled to a target control state by a feedforward controller 202 and a feedback controller 203. The feedforward controller 202 generates a feedforward signal for feedforward-controlling the stage 205 based on the drive profile signal 201. The feedback controller 203 generates a feedback signal for feedback-controlling the stage 205 based on the state quantity of the stage 205. Hence, the feedforward signal generated by the feedforward controller 202 and the feedback signal generated by the feedback controller 203 are the input signals, that is, the operation signals to the driving circuit of the stage 205.

Here, the state quantity of the stage 205 is a physical quantity indicating the state of the stage 205 and is the position of the stage 205 in this embodiment. However, the state quantity of the stage 205 may be the velocity, acceleration, jerk, or snap of the stage 205. Also, in this embodiment, as an acquisition unit that acquires the state quantity of the stage 205, a measurement unit including an interferometer or an encoder and configured to measure the position of the stage 205 is provided.

When the stage 205 is driven, a reaction force associated with driving of the stage 205 is generated. The reaction force is a factor that generates a main body vibration 209 of the substrate processing apparatus through a transfer characteristic 211 to (the main body structure of) the substrate processing apparatus to which the stage apparatus 100 is applied. FIG. 2 assumes a case where the characteristic varies by a variation amount A with respect to an average dynamic characteristic Pw of the stage 205. The variation amount A is generated by, for example, the position or aging of the stage 205.

According to this embodiment, in FIG. 2, there is provided a technique for reducing (canceling), by the reaction force processing mechanism 30, the main body vibration 209 that is the influence of a reaction force 210 associated with driving of the stage 205.

The reaction force A (210) transmitted to the substrate processing apparatus in association with the driving of the stage 205 is expressed as

$$\\ \begin{matrix}\frac{{rH}_{wd} ( {P}_{w} + Δ ) ( {C}_{w} + {F}_{w} )}{1 + {C}_{w} ( {P}_{w} + Δ )} & ( 1 )\end{matrix}$$

Also, a thrust B (212) output (generated) from the reaction force processing mechanism 30 is expressed as

$$\\ \begin{matrix}{rP}_{d} \{ \frac{{C}_{w} + {F}_{w}}{1 + {C}_{w} ( {P}_{w} + Δ )} {F}_{u} + {F}_{r} \} & ( 2 )\end{matrix}$$

Hence, the difference (synthetic force) between the reaction force A (210) indicated by expression (1) and the thrust B (212) indicated by expression (2) appears as the main body vibration y (209).

In this embodiment, the first controller Fr (207) and the second controller Fu (206) are set such that the influence of the reaction force A (210) associated with the driving of the stage 205 is reduced, preferably, the main body vibration y (209) becomes zero. In addition, the first controller Fr (207) and the second controller Fu (206) are set such that the influence of the variation of the dynamic characteristic of the stage 205 does not occur. This makes it possible to cancel the reaction force A (210) by the thrust B (212) regardless of the variation amount A. More specifically, values are obtained from equations that make the difference between expression (1) (reaction force A (210)) and expression (2) (thrust B (212)) zero, and the first controller Fr (207) and the second controller Fu (206) are set in accordance with

$$\\ \begin{matrix}{F}_{r} = ( \frac{{C}_{w} + {F}_{w}}{{C}_{w}} ) \frac{{H}_{wd}}{{P}_{d}} & ( 3 )\end{matrix}$$

$$\\ \begin{matrix}{F}_{u} = ( - \frac{1}{{C}_{w}} ) \frac{{H}_{wd}}{{P}_{d}} & ( 4 )\end{matrix}$$

Each of the feedback controller C_{w} (203), the feedforward controller F_{w} (202), a dynamic characteristic P_{d} of the reaction force processing mechanism 30, and the transfer characteristic H_{wd} (211) can be obtained in advance by pre-calculation, system identification, or the like. Hence, the first controller Fr (207) and the second controller Fu (206) can be set as indicated by equations (3) and (4).

As described above, in this embodiment, the first controller Fr (207) and the second controller Fu (206) are appropriately set based on the drive profile signal 201 and the circuit input signal 204. The first controller Fr (207) and the second controller Fu (206) are thus designed such that the reaction force processing mechanism 30 outputs the thrust B for reducing the influence of the reaction force A associated with the driving of the stage 205 without being affected by the variation of the dynamic characteristic of the stage 205. The first controller Fr (207) and the second controller Fu (206), which are thus designed, function as a generation unit that generates, based on the drive profile signal 201 and the circuit input signal 204, a thrust signal indicating a thrust that the reaction force processing mechanism 30 should output. Particularly, in this embodiment, the first controller Fr (207) and the second controller Fu (206) generate a thrust signal that makes the difference between the reaction force A and the thrust B zero. Note that setting the first controller Fr (207) and the second controller Fu (206) means deciding (adjusting) a parameter for generating the thrust signal in each controller.

Also, when a plurality of generation units (controllers) configured to generate a thrust signal to be input to the reaction force processing mechanism 30 are provided, it is possible to implement a system capable of improving the degree of freedom of adjustment and having an excellent disturbance resistance.

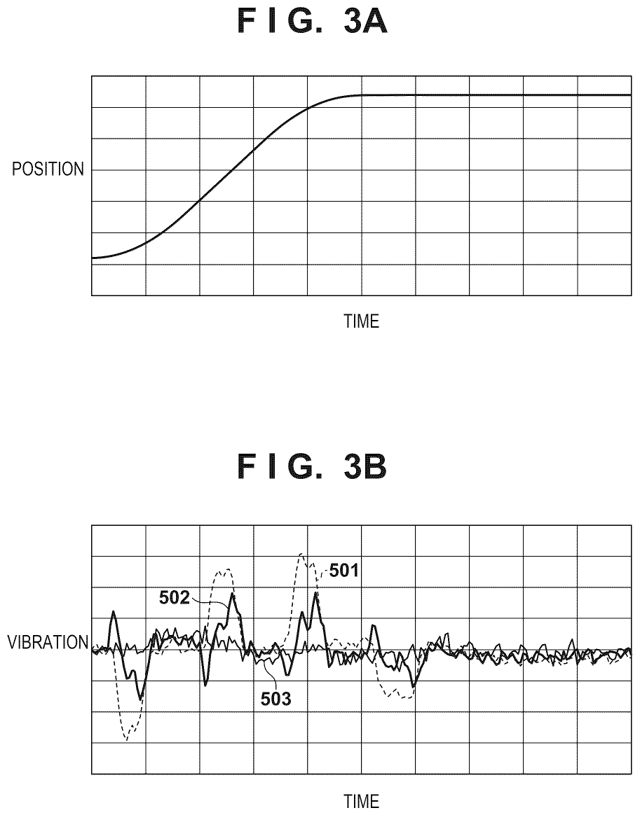

The effect implemented by this embodiment in the stage apparatus 100, that is, the effect of reducing the influence of the reaction force associated with driving of the stage 205 will be described with reference to FIGS. 3A and 3B.

FIG. 3A is a view showing the position (displacement) of the stage 205 when the stage 205 is step-driven. In FIG. 3A, the ordinate indicates the position of the stage 205, and the abscissa indicates time (elapsed time) from the start of step driving. FIG. 3B is a view showing the vibration of the base 5 acquired when the dynamic characteristic of the stage 205 varies during step driving of the stage 205 (FIG. 3A). In FIG. 3B, the ordinate indicates the vibration of the base 5, and the abscissa indicates time (elapsed time) from the start of step driving. FIG. 3B shows a waveform 501 indicating the vibration of the base 5 in a conventional technique and waveforms 502 and 503 indicating the vibration of the base 5 in this embodiment. The waveform 502 is a waveform in a case where the first controller Fr (207) and the second controller Fu (206) are set based on the drive profile signal 201 and the circuit input signal 204. The waveform 503 is a waveform in a case where the first controller Fr (207) and the second controller Fu (206) are set in accordance with equations (3) and (4).

When the waveform 501 is compared with the waveforms 502 and 503, as shown in FIG. 3B, in this embodiment, it is found that the vibration of the base 5 is smaller as compared to the conventional technique. Also, when the waveform 502 is compared with the waveform 503, it is found that the vibration of the base 5 can be made smaller by setting the first controller Fr (207) and the second controller Fu (206) in accordance with equations (3) and (4).

### Second Embodiment

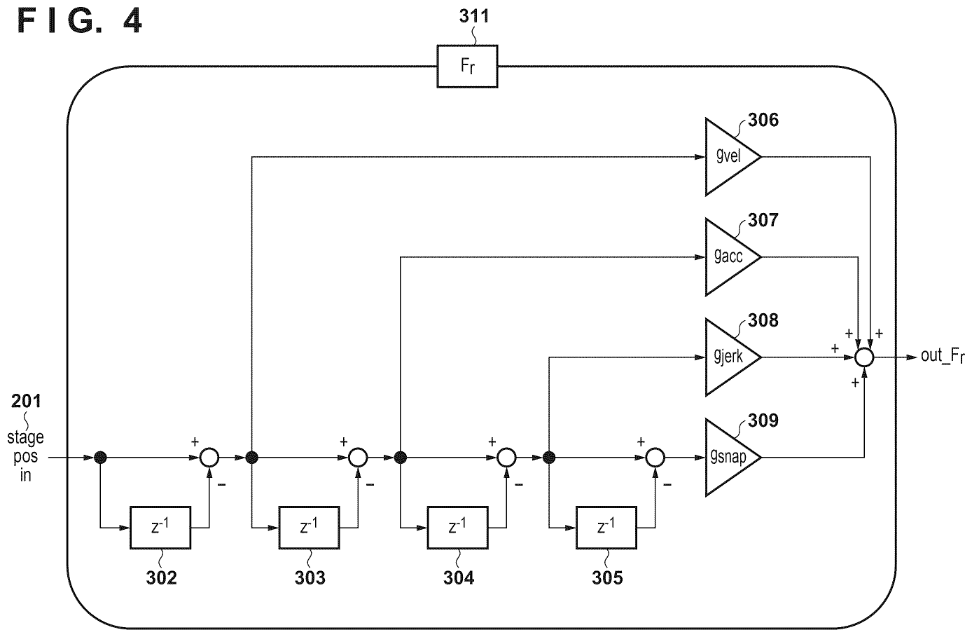

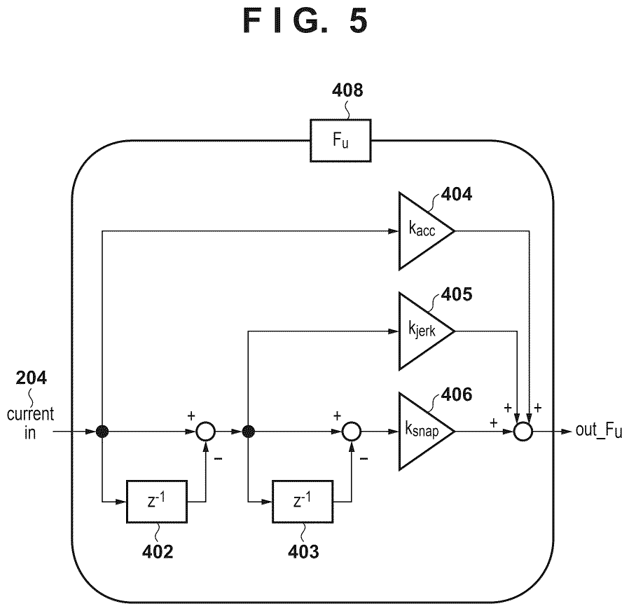

Detailed configurations of a first controller Fr (207) and a second controller Fu (206) will be described with reference to FIGS. 4 and 5. In this embodiment, an example in which control of a stage 205 or control of a reaction force processing mechanism 30 is implemented by discrete control using a computing element such as a microcontroller or a digital signal processor (DSP) will be described. FIG. 4 is a block diagram illustrating an example of the internal configuration of the first controller Fr (207) that receives a drive profile signal 201 as an input. FIG. 5 is a block diagram illustrating an example of the internal configuration of the second controller Fu (206) that receives a circuit input signal 204 as an input.

In FIGS. 4 and 5, each block indicates a Z-transformed (Laplace-transformed) block. Blocks Z−1 (302 to 305, 402, and 403) are operators each configured to generate a 1-sample delay for the input signal. The difference between a plurality of orders is obtained for each sampling, and gains gᵥₑₗ (306), g_{acc} (307), gⱼₑᵣₖ (308), gₛₙₐₚ (309), k_{acc} (404), kⱼₑᵣₖ (405), and kₛₙₐₚ (406) are applied to the discrete differentiation results of dimensions. In this embodiment, signals to which these gains are applied are the input signals to the reaction force processing mechanism 30.

In FIG. 4, the drive profile signal 201 is a position profile signal (position instruction). A gain can be set for each of the velocity dimension (vel) of the first order difference of the drive profile signal 201, the acceleration dimension (acc) of the second order difference, the jerk dimension (jerk) of the third order difference, and the snap dimension (snap) of the fourth order difference. A signal obtained by integrating the signals of all the dimensions is the output signal, that is, the input signal to the reaction force processing mechanism 30. In the first controller Fr (207), the transfer characteristic from the input to the output is represented by

$$\\ \begin{matrix}{g}_{vel} ( 1 - {z}^{- 1} ) + {{g}_{acc} ( 1 - {z}^{- 1} )}^{2} + {{g}_{jerk} ( 1 - {z}^{- 1} )}^{3} + {{g}_{- 1} ( 1 - {z}^{- 1} )}^{4} & ( 5 )\end{matrix}$$

As described above, in this embodiment, the first controller Fr (207) is configured to include individual controllers corresponding to a plurality of different characteristics obtained by decomposing the drive profile signal 201. If the drive profile signal 201 is a position profile signal, the plurality of characteristics are the snap characteristic, the jerk characteristic, the acceleration characteristic, and the velocity characteristic, as described above.

In FIG. 5, the circuit input signal 204 is an acceleration profile signal (acceleration instruction) indicating the transition of the acceleration of the stage 205. A gain can be set for each of the jerk dimension (jerk) of the first order difference of the circuit input signal 204 and the snap dimension (snap) of the second order difference. A signal obtained by integrating the signals of all the dimensions is the output signal, that is, the input signal to the reaction force processing mechanism 30. In the second controller Fu (206), the transfer characteristic from the input to the output is represented by

$$\\ \begin{matrix}{k}_{acc} + {k}_{jerk} ( 1 - {z}^{- 1} ) + {{k}_{snap} ( 1 - {z}^{- 1} )}^{2} & ( 6 )\end{matrix}$$

As described above, in this embodiment, the second controller Fu (206) is configured to include individual controllers corresponding to a plurality of different characteristics obtained by decomposing the circuit input signal 204. If the circuit input signal 204 is an acceleration profile signal, the plurality of characteristics are the snap characteristic and the jerk characteristic, as described above.

In this embodiment, for the first controller Fr (207) indicated by expression (5) and the second controller Fu (206) indicated by expression (6), the value (parameter) of the gain of each dimension is decided (adjusted) such that equations (3) and (4) are satisfied. Thus, controllers capable of reducing the influence of the variation of the dynamic characteristic of the stage 205 or the influence of the reaction force associated with driving of the stage 205 can be obtained.

In this embodiment, the number of parameters of gains is relatively as small as 7 and, therefore, the operation amounts of the controllers can be made small. Note that, in this embodiment, differentials up to the snap dimension (snap) are applied, but higher differential dimensions (Crackle, Pop, . . . ) may be applied. Also, a velocity characteristic or a position characteristic may be used by applying integration.

When the controllers are provided by decomposition to the characteristics of difference dimensions as physical quantities, it is possible to construct a system that specifies and corrects a thrust difference caused by a disturbance except the acceleration characteristic generated by default disturbance elements in the stage apparatus 100 and obtains an excellent disturbance resistance. Note that the default disturbance elements include, for example, an implementation spring element, an attenuation element caused by a magnetic circuit, an actuator difference between a stage linear motor and a reaction linear motor, and a thrust variation in an actuator.

### Third Embodiment

As described with reference to FIG. 1, in this embodiment, a stage 205 includes a first stage 1 that moves in the Y direction and a second stage 2 that moves in the X direction. In this case, a reaction force processing mechanism 30 functioning as a thrust unit, and a first controller Fr (207) and a second controller Fu (206) each of which functions as a generation unit are preferably provided for each of the first stage 1 and the second stage 2. The controllers corresponding to the stages (reaction force processing mechanisms) thus have different parameters. Hence, even if different disturbances occur in the X direction and the Y direction, it is possible to reduce the influence of the reaction force associated with driving of each stage without damaging the disturbance resistance.

### Fourth Embodiment

The parameters of a first controller Fr (207) and a second controller Fu (206) are preferably decided based on an evaluation value associated with at least one of the acceleration, velocity, and deviation of a stage 205 at a target position. In this embodiment, using these as evaluation values, the parameters of individual controllers are decided from the data of the evaluation values in the regions of the snap characteristic, jerk characteristic, velocity characteristic, and position characteristic at the time of driving of the stage 205. Note that the target position can arbitrarily be set and includes, for example, a position where the influence of the reaction force associated with driving of the stage 205 should be reduced most.

### Fifth Embodiment

In a stage apparatus 100, the evaluation value associated with at least one of the acceleration, velocity, and deviation of a stage 205 at a target position may change beyond a predetermined value. In this case, a control unit 90 preferably notifies that the parameters of a first controller Fr (207) and a second controller Fu (206) should be decided again (readjusted), for example, proposal of decision of new parameters. This notification is made, for example, by displaying an image or outputting a voice via a user interface provided in the stage apparatus 100. Also, in place of the notification or in addition to the notification, the control unit 90 may decide the parameters of the first controller Fr (207) and the second controller Fu (206) again.

### Sixth Embodiment

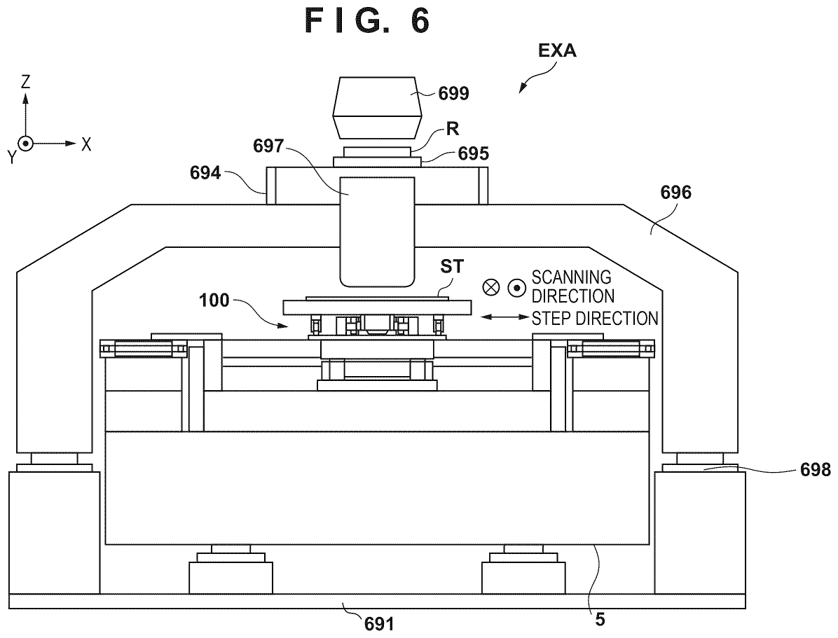

A stage apparatus 100 is applied to a substrate processing apparatus that processes a substrate ST, as described above. The substrate processing apparatus includes a lithography apparatus used in a lithography process of various kinds of devices to form a pattern on a substrate and, in this embodiment, is embodied as an exposure apparatus EXA that exposes the substrate ST via an original R, as shown in FIG. 6. FIG. 6 is a schematic view illustrating configurations of the exposure apparatus EXA according to an aspect of the present disclosure. In this embodiment, the exposure apparatus EXA is a step-and-scan type exposure apparatus (scanner) that exposes the substrate ST while relatively moving (scanning) the original R and the substrate ST in a scanning direction, and transfers the pattern of the original R to the substrate ST.

As shown in FIG. 6, the exposure apparatus EXA includes the stage apparatus 100, a lens barrel base 696, a damper 698, an original base 694, and an original stage 695. Also, the exposure apparatus EXA includes, as processing units for processing the substrate ST, a projection optical system 697 and an illumination optical system 699. In this embodiment, a direction perpendicular to the paper surface of FIG. 6 is defined as a scanning direction and a horizontal direction within the paper surface of FIG. 6 is defined as a step direction. A coordinate system is defined in which the scanning direction is set as the Y direction, a direction intersecting the scanning direction, particularly, the step direction orthogonal to the scanning direction is set as the X direction, and a direction orthogonal to the X and Y directions is set as the Z direction.

A base 5 is supported by a floor 691 via a mount (not shown). A substrate stage (a first stage 1 and a second stage 2) that holds the substrate ST is provided on the base 5. Also, a linear motor is provided as a driving unit (a first driving unit 10 and a second driving unit 20) that drives the substrate stage. The lens barrel base 696 is supported by the floor 691 via the damper 698. The projection optical system 697 and the original base 694 are provided on the lens barrel base 696. The original stage 695 that holds the original R and moves is provided on the original base 694. The illumination optical system 699 is provided above the original stage 695.

In exposure, light emitted from a light source (not shown) illuminates the original R by the illumination optical system 699. The pattern of the original R is projected (formed), via the projection optical system 697, onto the substrate ST held by the stage apparatus 100. At this time, the original stage 695 and a substrate stage 600 relatively move the original R and the substrate ST in the scanning direction, respectively. Therefore, the exposure apparatus EXA can economically provide a device (an article such as a semiconductor element, a magnetic storage medium, or a liquid crystal display element) at high throughput.

Note that, in the present disclosure, the lithography apparatus is not limited to the exposure apparatus, and it may be applied to, for example, an imprint apparatus or a drawing apparatus. The imprint apparatus brings an imprint material supplied (arranged) on a substrate into contact with a mold (original), and applies curing energy to the imprint material, thereby forming a pattern of a cured product to which the pattern of the mold is transferred. The drawing apparatus forms a pattern (latent image pattern) on a substrate by drawing on the substrate using a charged particle beam (electron beam) or a laser beam. Also, the present disclosure can be applied to a substrate processing apparatus using a stage apparatus, such as a conveyance apparatus, a machining apparatus, a production apparatus, a precision machining apparatus, and a precision measurement apparatus.

### Seventh Embodiment

An article manufacturing method according to the embodiment of the present disclosure is favorable in, for example, manufacturing such articles as devices (for example, a semiconductor element, a magnetic storage medium, and a liquid crystal display element). The manufacturing method includes a process of forming a pattern on a substrate using the exposure apparatus EXP, a process of processing the substrate with the pattern formed thereon, and a process of manufacturing an article from the processed substrate. Also, the manufacturing method can include other known processes (oxidization, film formation, vapor deposition, doping, planarization, etching, photoresist stripping, dicing, bonding, packaging, and the like). Compared to the conventional ones, the article manufacturing method according to this embodiment is advantageous in at least one of the performance, quality, productivity, and production cost of an article.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent application No. 2025-009332 filed on Jan. 22, 2025, which is hereby incorporated by reference herein in its entirety.

What is claimed is:

1. A stage apparatus comprising:
a stage configured to hold an object;
a driving unit configured to drive the stage;
a thrust unit configured to output a thrust to reduce influence of a reaction force associated with the driving of the stage by the driving unit; and
a generation unit configured to generate a thrust signal indicating the thrust that the thrust unit should output, based on a profile signal indicating a control target of the stage and an operation signal indicating an operation amount of the stage to be input to the driving unit.

2. The apparatus according to claim 1, wherein the control target includes a trajectory of a target position of the stage.

3. The apparatus according to claim 1, wherein the control target includes a transition of a target velocity of the stage.

4. The apparatus according to claim 1, wherein the generation unit generates the thrust signal such that a difference between the reaction force associated with the driving of the stage by the driving unit and the thrust output from the thrust unit becomes zero.

5. The apparatus according to claim 1, wherein
the generation unit includes:
a first controller for the profile signal; and
a second controller for the operation signal.

6. The apparatus according to claim 5, wherein the first controller includes individual controllers corresponding to a plurality of different characteristics obtained from the profile signal.

7. The apparatus according to claim 6, wherein
the profile signal indicates a trajectory of a target position of the stage, and
the plurality of characteristics include a snap characteristic, a jerk characteristic, an acceleration characteristic, a velocity characteristic, and a position characteristic.

8. The apparatus according to claim 5, wherein the second controller includes individual controllers corresponding to a plurality of different characteristics obtained from the operation signal.

9. The apparatus according to claim 8, wherein
the operation signal indicates a transition of an acceleration of the stage, and
the plurality of characteristics include a snap characteristic and a jerk characteristic.

10. The apparatus according to claim 1, wherein
the stage includes a first stage that moves in a first direction, and a second stage that moves in a second direction different from the first direction, and
the thrust unit and the generation unit are provided for each of the first stage and the second stage.

11. The apparatus according to claim 1, wherein for the generation unit, a parameter for generating the thrust signal is decided based on an evaluation value associated with at least one of an acceleration, a velocity, and a deviation of the stage at a position where the influence of the reaction force associated with the driving of the stage should be reduced most.

12. The apparatus according to claim 11, further comprising a control unit configured to notify that the parameter should be decided again in a case where the evaluation value changes beyond a predetermined value.

13. The apparatus according to claim 11, further comprising a control unit configured to decide the parameter again in a case where the evaluation value changes beyond a predetermined value.

14. A substrate processing apparatus for processing a substrate, comprising:
a stage apparatus defined in claim 1, which is configured to hold the substrate as an object; and
a processing unit configured to process the substrate held by the stage apparatus.

15. The apparatus according to claim 14, wherein the processing unit includes a projection optical system configured to project a pattern of an original onto the substrate.

16. An article manufacturing method comprising:
forming a pattern on a substrate using a substrate processing apparatus defined in claim 14;
processing the substrate on which the pattern is formed in the forming; and
manufacturing an article from the processed substrate.
